(19) United States
(12) Patent Application Publication
(10) Pub. No.: US 2025/0331124 A1
(43) Pub. Date: Oct. 23, 2025

(54) UNIVERSAL PERIPHERAL COMPONENT INTERCONNECT EXPRESS ADD-IN CARD

(71) Applicant: DELL PRODUCTS L.P., Round Rock, TX (US)

(72) Inventors: Kang-Wei Fan, ZhongLi District (TW); Tung-Yi Chen, Banciao (TW); Yu-Ming Kuo, New Taipei City (TW)

(21) Appl. No.: 18/643,477

(22) Filed: Apr. 23, 2024

(51) Int. Cl. H05K 7/20; G06F 1/18

(52) U.S. Cl. CPC H05K 7/20145; G06F 1/186; H05K 7/20172

(57) ABSTRACT

An information handling system has a chassis enclosure that includes a graphics card with an exhaust fin. An add-in card is disposed adjacent to the graphics card and is configured to direct airflow from the exhaust fin through vent holes of the graphics card.

### FIELD OF THE DISCLOSURE

The present disclosure generally relates to information handling systems, and more particularly relates to a universal peripheral component interconnect express add-in card.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system has a chassis enclosure that includes a graphics card with an exhaust fin. An add-in card is disposed adjacent to the graphics card and is configured to direct airflow from the exhaust fin through vent holes of the graphics card.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram illustrating an information handling system according to an embodiment of the present disclosure;

FIGS. 2 and 3 are perspective views of a graphics card and a peripheral component interconnect express (PCIe) add-in card, according to an embodiment of the present disclosure;

FIG. 4 is a perspective view of a section of a PCIe add-in card, according to an embodiment of the present disclosure;

FIG. 5 is a perspective view of a PCIe add-in card, according to an embodiment of the present disclosure;

FIG. 6 is an exploded perspective view of a PCIe add-in card, according to an embodiment of the present disclosure;

FIG. 7 is a perspective view of a PCIe add-in card, according to an embodiment of the present disclosure; and

FIG. 8 is a perspective view of a PCIe add-in card and graphics card, according to an embodiment of the present disclosure;

FIG. 9 is a perspective view of a section of a PCIe add-in card, according to an embodiment of the present disclosure;

FIG. 10 is a perspective view of a section of a PCIe slot, according to an embodiment of the present disclosure; and

FIG. 11 is a perspective view of a PCIe add-in card and graphics card, according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

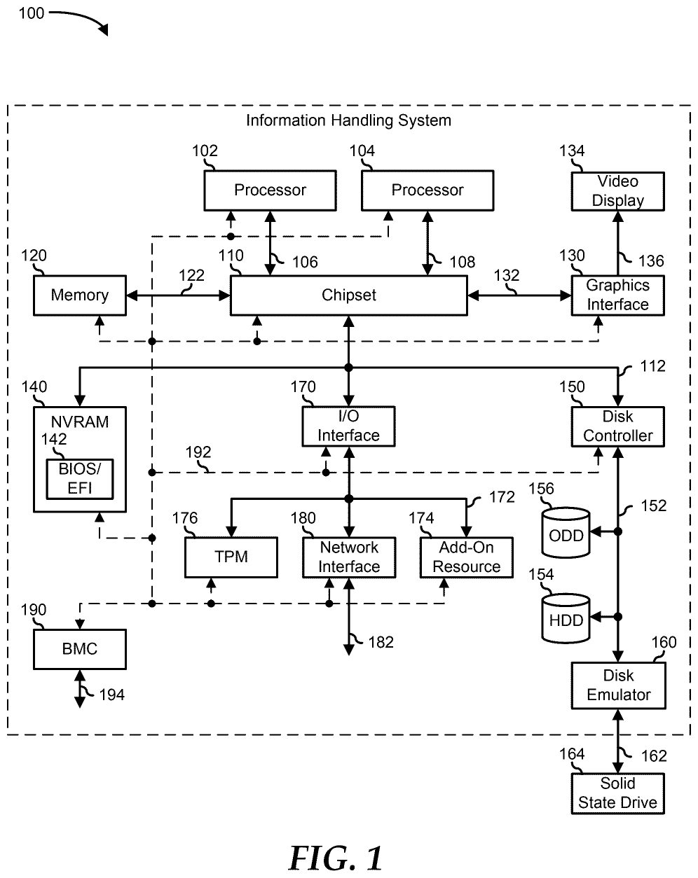

FIG. 1 illustrates an embodiment of an information handling system 100 including processors 102 and 104, a chipset 110, a memory 120, a graphics adapter 130 connected to a video display 134, a non-volatile RAM (NVRAM) 140 that includes a basic input and output system/extensible firmware interface (BIOS/EFI) module 142, a disk controller 150, a hard disk drive (HDD) 154, an optical disk drive 156, a disk emulator 160 connected to a solid-state drive (SSD) 164, an input/output (I/O) interface 170 connected to an add-on resource 174 and a trusted platform module (TPM) 176, a network interface 180, and a baseboard management controller (BMC) 190. Processor 102 is connected to chipset 110 via processor interface 106, and processor 104 is connected to the chipset via processor interface 108. In a particular embodiment, processors 102 and 104 are connected together via a high-capacity coherent fabric, such as a HyperTransport link, a QuickPath Interconnect, or the like. Chipset 110 represents an integrated circuit or group of integrated circuits that manage the data flow between processors 102 and 104 and the other elements of information handling system 100. In a particular embodiment, chipset 110 represents a pair of integrated circuits, such as a northbridge component and a southbridge component. In another embodiment, some or all of the functions and features of chipset 110 are integrated with one or more of processors 102 and 104.

Memory 120 is connected to chipset 110 via a memory interface 122. An example of memory interface 122 includes a Double Data Rate (DDR) memory channel and memory 120 represents one or more DDR Dual In-Line Memory Modules (DIMMs). In a particular embodiment, memory interface 122 represents two or more DDR channels. In another embodiment, one or more of processors 102 and 104 include a memory interface that provides a dedicated memory for the processors. A DDR channel and the connected DDR DIMMs can be in accordance with a particular DDR standard, such as a DDR3 standard, a DDR4 standard, a DDR5 standard, or the like.

Memory 120 may further represent various combinations of memory types, such as Dynamic Random Access Memory (DRAM) DIMMs, Static Random Access Memory (SRAM) DIMMs, non-volatile DIMMs (NV-DIMMs), storage class memory devices, Read-Only Memory (ROM) devices, or the like. Graphics adapter 130 is connected to chipset 110 via a graphics interface 132 and provides a video display output 136 to a video display 134. An example of a graphics interface 132 includes a Peripheral Component Interconnect-Express (PCIe) interface and graphics adapter 130 can include a four-lane (x4) PCIe adapter, an eight-lane (x8) PCIe adapter, a 16-lane (x16) PCIe adapter, or another configuration, as needed or desired. In a particular embodiment, graphics adapter 130 is provided down on a system printed circuit board (PCB). Video display output 136 can include a Digital Video Interface (DVI), a High-Definition Multimedia Interface (HDMI), a DisplayPort interface, or the like, and video display 134 can include a monitor, a smart television, an embedded display such as a laptop computer display, or the like.

NVRAM 140, disk controller 150, and I/O interface 170 are connected to chipset 110 via an I/O channel 112. An example of I/O channel 112 includes one or more point-to-point PCIe links between chipset 110 and each of NVRAM 140, disk controller 150, and I/O interface 170. Chipset 110 can also include one or more other I/O interfaces, including a PCIe interface, an Industry Standard Architecture (ISA) interface, a Small Computer Serial Interface (SCSI) interface, an Inter-Integrated Circuit (I²C) interface, a System Packet Interface, a Universal Serial Bus (USB), another interface, or a combination thereof. NVRAM 140 includes BIOS/EFI module 142 that stores machine-executable code (BIOS/EFI code) that operates to detect the resources of information handling system 100, to provide drivers for the resources, to initialize the resources, and to provide common access mechanisms for the resources. The functions and features of BIOS/EFI module 142 will be further described below.

Disk controller 150 includes a disk interface 152 that connects the disc controller to a hard disk drive (HDD) 154, to an optical disk drive (ODD) 156, and to disk emulator 160. An example of disk interface 152 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 160 permits SSD 164 to be connected to information handling system 100 via an external interface 162. An example of external interface 162 includes a USB interface, an institute of electrical and electronics engineers (IEEE) 1394 (Firewire) interface, a proprietary interface, or a combination thereof. Alternatively, SSD 164 can be disposed within information handling system 100.

I/O interface 170 includes a peripheral interface 172 that connects the I/O interface to add-on resource 174, to TPM 176, and to network interface 180. Peripheral interface 172 can be the same type of interface as I/O channel 112 or can be a different type of interface. As such, I/O interface 170 extends the capacity of I/O channel 112 when peripheral interface 172 and the I/O channel are of the same type, and the I/O interface translates information from a format suitable to the I/O channel to a format suitable to the peripheral interface 172 when they are of a different type. Add-on resource 174 can include a data storage system, an additional graphics interface, a network interface card (NIC), a sound/video processing card, another add-on resource, or a combination thereof. Add-on resource 174 can be on a main circuit board, on separate circuit board, or add-in card disposed within information handling system 100, a device that is external to the information handling system, or a combination thereof.

Network interface 180 represents a network communication device disposed within information handling system 100, on a main circuit board of the information handling system, integrated onto another component such as chipset 110, in another suitable location, or a combination thereof. Network interface 180 includes a network channel 182 that provides an interface to devices that are external to information handling system 100. In a particular embodiment, network channel 182 is of a different type than peripheral interface 172 and network interface 180 translates information from a format suitable to the peripheral channel to a format suitable to external devices.

In a particular embodiment, network interface 180 includes a NIC or host bus adapter (HBA), and an example of network channel 182 includes an InfiniBand channel, a Fibre Channel, a Gigabit Ethernet channel, a proprietary channel architecture, or a combination thereof. In another embodiment, network interface 180 includes a wireless communication interface, and network channel 182 includes a Wi-Fi channel, a near-field communication (NFC) channel, a Bluetooth® or Bluetooth-Low-Energy (BLE) channel, a cellular based interface such as a Global System for Mobile (GSM) interface, a Code-Division Multiple Access (CDMA) interface, a Universal Mobile Telecommunications System (UMTS) interface, a Long-Term Evolution (LTE) interface, or another cellular based interface, or a combination thereof. Network channel 182 can be connected to an external network resource (not illustrated). The network resource can include another information handling system, a data storage system, another network, a grid management system, another suitable resource, or a combination thereof.

BMC 190 is connected to multiple elements of information handling system 100 via one or more management interface 192 to provide out of band monitoring, maintenance, and control of the elements of the information handling system. As such, BMC 190 represents a processing device different from processor 102 and processor 104, which provides various management functions for information handling system 100. For example, BMC 190 may be responsible for power management, cooling management, and the like. The term BMC is often used in the context of server systems, while in a consumer-level device, a BMC may be referred to as an embedded controller (EC). A BMC included in a data storage system can be referred to as a storage enclosure processor. A BMC included at a chassis of a blade server can be referred to as a chassis management controller and embedded controllers included at the blades of the blade server can be referred to as blade management controllers. Capabilities and functions provided by BMC 190 can vary considerably based on the type of information handling system. BMC 190 can operate in accordance with an Intelligent Platform Management Interface (IPMI). Examples of BMC 190 include an Integrated Dell® Remote Access Controller (iDRAC).

Management interface 192 represents one or more out-of-band communication interfaces between BMC 190 and the elements of information handling system 100, and can include an Inter-Integrated Circuit (I2C) bus, a System Management Bus (SMBUS), a Power Management Bus (PMBUS), a Low Pin Count (LPC) interface, a serial bus such as a Universal Serial Bus (USB) or a Serial Peripheral Interface (SPI), a network interface such as an Ethernet interface, a high-speed serial data link such as a PCIe interface, a Network Controller Sideband Interface (NC-SI), or the like. As used herein, out-of-band access refers to operations performed apart from a BIOS/operating system execution environment on information handling system 100, that is apart from the execution of code by processors 102 and 104 and procedures that are implemented on the information handling system in response to the executed code.

BMC 190 operates to monitor and maintain system firmware, such as code stored in BIOS/EFI module 142, option ROMs for graphics adapter 130, disk controller 150, add-on resource 174, network interface 180, or other elements of information handling system 100, as needed or desired. In particular, BMC 190 includes a network interface 194 that can be connected to a remote management system to receive firmware updates, as needed or desired. Here, BMC 190 receives the firmware updates, stores the updates to a data storage device associated with the BMC, and transfers the firmware updates to the NVRAM of the device or system that is the subject of the firmware update, thereby replacing the currently operating firmware associated with the device or system, and reboots information handling system, whereupon the device or system utilizes the updated firmware image.

BMC 190 utilizes various protocols and application programming interfaces (APIs) to direct and control the processes for monitoring and maintaining the system firmware. An example of a protocol or API for monitoring and maintaining the system firmware includes a graphical user interface (GUI) associated with BMC 190, an interface defined by the Distributed Management Taskforce (DMTF) (such as a Web Services Management (WSMan) interface, a Management Component Transport Protocol (MCTP) or, a Redfish® interface), various vendor defined interfaces (such as a Dell EMC Remote Access Controller Administrator (RACADM) utility, a Dell EMC OpenManage Enterprise, a Dell EMC OpenManage Server Administrator (OMSA) utility, a Dell EMC OpenManage Storage Services (OMSS) utility, or a Dell EMC OpenManage Deployment Toolkit (DTK) suite), a BIOS setup utility such as invoked by a “F2” boot option, or another protocol or API, as needed or desired.

In a particular embodiment, BMC 190 is included on a main circuit board (such as a baseboard, a motherboard, or any combination thereof) of information handling system 100 or is integrated onto another element of the information handling system such as chipset 110, or another suitable element, as needed or desired. As such, BMC 190 can be part of an integrated circuit or a chipset within information handling system 100. An example of BMC 190 includes an iDRAC, or the like. BMC 190 may operate on a separate power plane from other resources in information handling system 100. Thus BMC 190 can communicate with the management system via network interface 194 while the resources of information handling system 100 are powered off. Here, information can be sent from the management system to BMC 190 and the information can be stored in a RAM or NVRAM associated with the BMC. Information stored in the RAM may be lost after power-down of the power plane for BMC 190, while information stored in the NVRAM may be saved through a power-down/power-up cycle of the power plane for the BMC.

Information handling system 100 can include additional components and additional busses, not shown for clarity. For example, information handling system 100 can include multiple processor cores, audio devices, and the like. While a particular arrangement of bus technologies and interconnections is illustrated for the purpose of example, one of skill will appreciate that the techniques disclosed herein are applicable to other system architectures. Information handling system 100 can include multiple central processing units (CPUs) and redundant bus controllers. One or more components can be integrated together. Information handling system 100 can include additional buses and bus protocols, for example, I2C and the like. Additional components of information handling system 100 can include one or more storage devices that can store machine-executable code, one or more communications ports for communicating with external devices, and various input and output (I/O) devices, such as a keyboard, a mouse, and a video display.

For purposes of this disclosure information handling system 100 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 100 can be a personal computer, a laptop computer, a smartphone, a tablet device or other consumer electronic device, a network server, a network storage device, a switch, a router, or another network communication device, or any other suitable device and may vary in size, shape, performance, functionality, and price. Further, information handling system 100 can include processing resources for executing machine-executable code, such as processor 102, a programmable logic array (PLA), an embedded device such as a System-on-a-Chip (SoC), or other control logic hardware. Information handling system 100 can also include one or more computer-readable media for storing machine-executable code, such as software or data.

An information handling system typically supports different form factors of a PCIe card. PCIe cards are internal devices, such as a graphics card that connects to a PCIe interface of an information handling system. The PCIe interface allows high bandwidth communication between PCIe cards and a motherboard, as well as other hardware of the information handling system. However, there are single-wide PCIe cards that have poor thermal performance. For example a typical single-wide graphics card may have poor thermal performance due to a ducting design on the graphics card, wherein the duct of the graphics card ends halfway to provide clearance for an I/O port. This ducting design provides a high chance of hot air re-circulating back to an inlet fan of the graphics card. To address the poor thermal performance, a typical solution is to add a system fan to prevent the hot air from recirculating. However, not all information handling systems may have the space for an additional fan. Also, the additional fan would raise the cost and complexity of the information handling system. Further, the additional fan may also increase the acoustics level of the information handling system. To address the above and other concerns, the present disclosure provides a ducting solution that can prevent the hot air from re-circulating back into the inlet of the PCIe card thereby reducing system temperature.

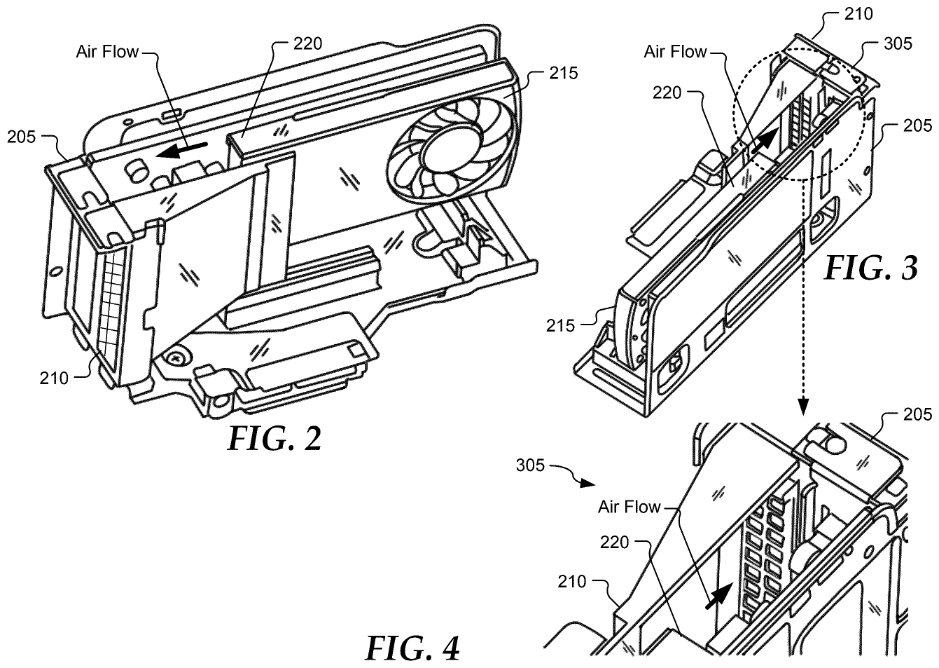

FIG. 2 shows a perspective view of a graphics card 205 and a PCIe add-in card 210. Graphics card 205 and PCIe add-in card 210 are plugged into mating PCIe slots, also referred to as PCIe sockets, of a motherboard. The motherboard is located within a chassis enclosure of an information handling system, which is similar to information handling system 100 of FIG. 1. In one embodiment, PCIe add-in card 210 may be plugged into a PCIe slot that is adjacent to a PCIe slot that graphics card 205 is plugged into. Accordingly, PCIe add-in card 210 may be mounted on a cutout of a panel of the chassis enclosure that is adjacent to another cutout on the panel of the chassis enclosure that graphics card 205 is mounted on. Graphics card 205, which is similar to graphics adapter 130 of FIG. 1, can be a single-wide PCIe video graphics card disposed next to a PCIe add-in card. Similarly, PCIe add-in card 210 may also be a single-wide PCIe add-in card.

In this example, graphics card 205 includes an intake fan 215 and an exhaust fin 220. Intake fan 215 typically draws air around graphics card 205 and blows the air out exhaust fin 220 which is on the other end of graphics card 205. Because exhaust fin 220 is typically located around the mid-section of graphics card 205, hot air from exhaust fin 220 generally re-circulates in the chassis enclosure of the information handling system instead of venting outside the chassis. Thus, the temperature of the information handling system may not cool down.

The placement of PCIe add-in card 210 adjacent to graphics card 205 may create a partition between intake fan 215 and exhaust fin 220. The partition may block and prevent the hot air from exhaust fin 220 from re-circulating inside the chassis enclosure. Instead, PCIe add-in card 210 may direct the hot air from exhaust fin 220 to flow through vent holes of PCIe add-in card 210 and out of the chassis enclosure. This allows hot air from exhaust fin 220 to flow out of the chassis of the information handling system which can assist in cooling graphics card 205 and/or the information handling system.

FIG. 3 shows a perspective view of graphics card 205 and PCIe add-in card 210. The perspective view includes a section 305 which depicts the airflow through vent holes of PCIe add-in card 210. In particular, PCIe add-in card 210 may be positioned adjacent to graphics card 205 to direct the airflow in a direction towards vent holes of PCIe add-in card 210 instead of re-circulating in the chassis. PCIe add-in card 210 may be configured to create a partition between an exhaust and intake of graphics card 205 which helps to prevent the hot exhaust air from recirculating inside the information handling system. This may prevent the hot air from re-circulating inside the information handling system. Accordingly, the inlet and/or outlet temperature of graphics card 205 of a CPU of the information handling system may be improved. In addition, the system acoustic of the information handling system may also be lowered.

FIG. 4 shows a perspective view of section 305 with an arrow depicting the airflow. The fan duct of PCIe add-in card 210 may be configured to create a partition between the exhaust fin 220 and intake fan 215 of graphics card 205. The partition may direct the airflow between PCIe add-in card 210 and graphics card 205 and out of the information handling system. In addition, the partition may be configured to block the airflow from re-circulating in the information handling system.

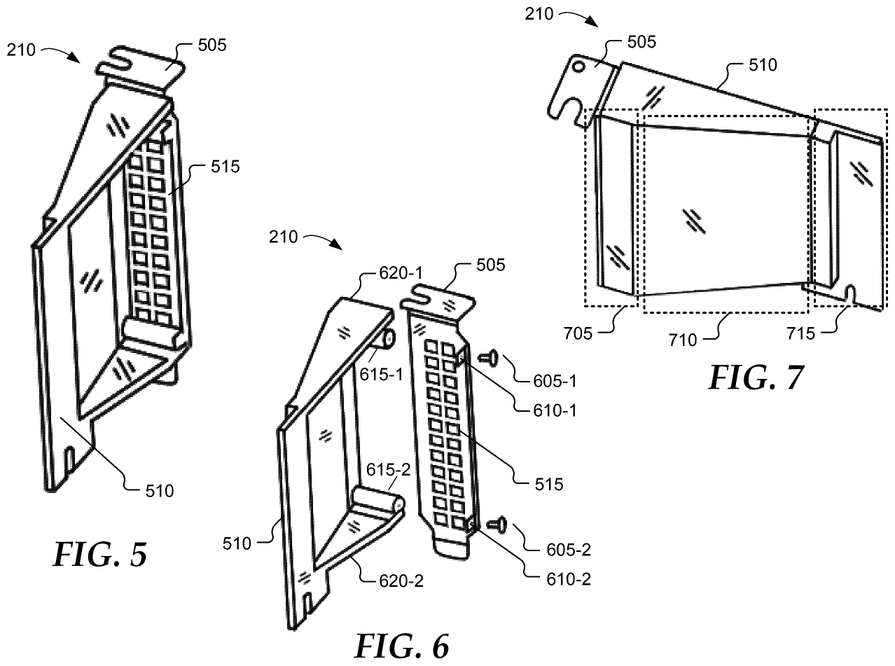

FIG. 5 shows a perspective view of PCIe add-in card 210 that includes a PCIe bracket 505 and a fan duct 510. PCIe bracket 505 and fan duct 510 may be physically coupled via one or more fasteners. PCIe bracket 505 may be used to mount PCIe add-in card 210 at a cutout of panel of the chassis enclosure. PCIe bracket 505 includes a plurality of vent holes 515 which allow the air from exhaust fin 220 to be vented out of the information handling system. PCIe bracket 505 and fan duct 510 may be fabricated using the same or different materials. For example, each one of PCIe bracket 505 and fan duct 510 may be fabricated from sheet metal, molded plastics (such as acrylonitrile butadiene styrene, acrylonitrile styrene acryl ester and polycarbonate, polyamide, polycarbonate, polycarbonate and acrylonitrile butadiene styrene, phenolharz, polymethyl methacrylate, Plexiglas®, polyphenylene ether, polyphenylene oxide, modified polyether, polystyrene, styrene-ethylene butadiene styrene or other suitable plastics), or other suitable materials.

FIG. 6 shows an exploded perspective view of PCIe add-in card 210 that includes PCIe bracket 505 and fan duct 510. Fan duct 510 includes support structures 620 and standoff nuts 615. PCIe bracket 505 that can be affixed to fan duct 510 using fasteners 605-1 and 605-2 via mounting holes at mounting members 610-1 and 610-2, respectively. Fasteners 605-1 and 605-2 may then thread through standoff nuts 615-1 and 615-2, respectively. Standoff nuts 615-1 and 615-2 may be affixed to support structures 620-1 and 620-2 of fan duct 510. Fasteners 605-1 and 605-2 may include at least one of a screw, a bolt, a clip, a snap fastener, or the like. Each one of support structures 620-1 and 620-2 may include at least one sloped edge and two straight edges, wherein the two straight edges may form a right angle.

FIG. 7 shows a perspective view of PCIe add-in card 210. PCIe add-in card 210 includes sections 705, 710, and 715 on one side. Section 710 may be disposed as a slope between sections 705 and 715. The slope may be designed such as to allow PCIe add-in card 210 to mate with a PCIe slot. Thus, no additional supporting bracket may be needed or desired to secure PCIe add-in card 210 in place. Support structures 620-1 and 620-2 may be disposed of on top and bottom of sections 705, 710, and 715.

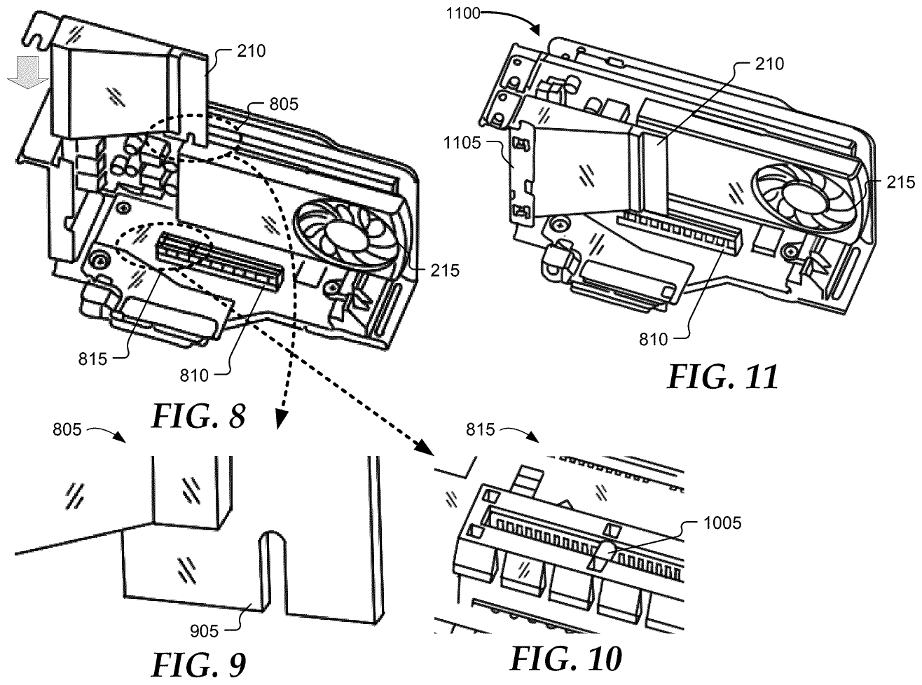

FIG. 8 shows a perspective view of PCIe add-in card 210 and graphics card 205, wherein graphics card 205 is affixed on a motherboard. PCIe add-in card 210 may be configured to be inserted and to fit into a PCIe slot 810, also referred to as a PCIe socket, of an information handling system similar to other PCIe add-in cards. For example, a section 805 of PCIe add-in card 210 may be inserted in a section 815 of PCIe slot 810. Section 805 may be a portion of section 715 of FIG. 7. PCIe add-in card 210 may be configured with a universal form factor that can fit into various widths of a standard PCIe slot without an additional support bracket or mounting mechanism. For example, a PCIe add-in card can be inserted into a PCIe x1 slot, a PCIe x4 slot, a PCIe x8 slot, a PCIe x16 slot, etc.

FIG. 9 shows a perspective view of section 805 of PCIe add-in card 210 of FIG. 8, wherein section 805 can be mated into section 815 of FIG. 8. Section 805 includes a notch 905 that is configured to fit into a positioning fixture 1005 of section 815 of PCIe slot 810 as depicted in FIG. 10 that shows a perspective view of section 815 of PCIe slot 810.

FIG. 11 shows a perspective view of PCIe add-in card 210 and graphics card 205 after PCIe add-in card 210 has been inserted into PCIe slot 810. In addition, PCIe add-in card 210 may be secured to a mounting bracket 1105 similar to other PCIe add-in cards. Mounting bracket 1105 can be part of the chassis of the information handling system.

Those of ordinary skill in the art will appreciate that the configuration, hardware, and/or software components of information handling system 200 depicted in FIG. 2 may vary. For example, the illustrative components within information handling system 200 are not intended to be exhaustive but rather are representative to highlight components that can be utilized to implement aspects of the present disclosure. For example, other devices and/or components may be used in addition to or in place of the devices/components depicted. The depicted example does not convey or imply any architectural or other limitations with respect to the presently described embodiments and/or the general disclosure. In the discussion of the figures, reference may also be made to components illustrated in other figures for continuity of the description.

While embodiments of the present disclosure are described in terms of managing airflow from graphics card 205 of FIG. 2, it should be recognized that PCIe add-in card 210 may be utilized to manage airflow from other types of PCIe devices configured with an intake fan and an exhaust fin, such as an SSD card, non-volatile memory express adapter card, among others. Further, while embodiments of the present disclosure are described in using a PCIe add-in card to manage the airflow, similar ducting systems such as via a PCI add-in card may be utilized without deviating from the scope of the present disclosure.

As used herein, a hyphenated form of a reference numeral refers to a specific instance of an element and the un-hyphenated form of the reference numeral refers to the collective or generic element. Thus, for example, fastener “605-1” refers to an instance of a fastener class, which may be referred to collectively as fasteners “605” and any one of which may be referred to generically as a fastener “605.”

When referred to as a “device,” a “module,” a “unit,” a “controller,” or the like, the embodiments described herein can be configured as hardware. For example, a portion of an information handling system device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device).

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents but also equivalent structures.

What is claimed is:

1. An add-in card comprising:
a bracket; and
a fan duct that is affixed to the bracket, wherein the fan duct is configured to create a partition between an exhaust fin and an intake fan of a graphics card that is disposed adjacent to the add-in card.

2. The add-in card of claim 1, wherein the add-in card is a single-wide PCIe add-in card.

3. The add-in card of claim 1, wherein the bracket includes vent holes.

4. The add-in card of claim 1, wherein the add-in card is disposed adjacent to the graphics card.

5. The add-in card of claim 1, wherein the fan duct is configured to direct airflow to vent holes of the bracket.

6. The add-in card of claim 1, wherein the fan duct includes a sloped side.

7. The add-in card of claim 1, wherein the fan duct includes a notch that is configured to mate with a PCIe socket.

8. The add-in card of claim 1, wherein the add-in card is a peripheral component interconnect express add-in card.

9. The add-in card of claim 1, wherein the add-in card is a peripheral component interconnect add-in card.

10. An information handling system, comprising:
a graphics card that includes an exhaust fin; and
a peripheral component interconnect express (PCIe) add-in card disposed adjacent to the graphics card and configured to direct airflow from the exhaust fin through vent holes of the PCIe add-in card.

11. The information handling system of claim 10, wherein the PCIe add-in card includes a fan duct that is configured to block the airflow from re-circulating in the information handling system.

12. The information handling system of claim 11, wherein the fan duct includes a sloped side.

13. The information handling system of claim 11, wherein the fan duct includes a notch that is configured to mate with a PCIe socket.

14. The information handling system of claim 11, wherein the fan duct is configured to create a partition between the exhaust fin and an intake fan of the graphics card.

15. An information handling system comprising:
a chassis enclosure that includes:
a graphics card that includes an exhaust fin; and
an add-in card disposed adjacent to the graphics card and configured to direct airflow from the exhaust fin through vent holes of the graphics card.

16. The information handling system of claim 15, wherein the add-in card includes a fan duct that is configured to block the airflow from re-circulating in the information handling system.

17. The information handling system of claim 16, wherein the fan duct includes a sloped side.

18. The information handling system of claim 16, wherein the fan duct includes a notch that is configured to mate with a PCIe socket.

19. The information handling system of claim 15, wherein the add-in card is a peripheral component interconnect express add-in card.

20. The information handling system of claim 15, wherein the add-in card is a peripheral component interconnect add-in card.
